(19) United States
(12) Patent Application Publication
(10) Pub. No.: US 2013/0099250 A1
(43) Pub. Date: Apr. 25, 2013

(54) STRUCTURE OF SEMICONDUCTOR CHIPS WITH ENHANCED DIE STRENGTH AND A FABRICATION METHOD THEREOF

(71) Applicant: Chang-Hwang HUA, Tao Yuan Shien (TW)

(72) Inventor: Chang-Hwang HUA, Tao Yuan Shien (TW)

(73) Assignee: WIN Semiconductors Corp.

(21) Appl. No.: 13/357,338

(22) Filed: Jan. 24, 2012

(30) Foreign Application Priority Data
Oct. 21, 2011 (TW) 100138248

(51) Int. Cl. H01L 29/16; H01L 29/20; H01L 21/78; H01L 23/48

(52) U.S. Cl. 257/77; 257/741; 257/76; 438/113; 257/E23.01; 257/E29.089; 257/E29.082; 257/E21.599

(57) ABSTRACT

An improved structure of semiconductor chips with enhanced die strength and a fabrication method thereof are disclosed. The improved structure comprises a substrate, an active layer, and a backside metal layer, in which the active layer is formed on the front side of the substrate and includes at least one integrated circuit; the backside metal layer is formed on the backside of the substrate, which fully covers the area corresponding to the area covered by the integrated circuits in the active layer. By using the specific dicing process of the present invention, the backside metal layer and the substrate can be diced tidily. Die cracking on the border between the substrate and the backside metal layer of the diced single chip can be prevented, and thereby the die strength can be significantly enhanced.

### FIELD OF THE INVENTION

The present invention relates to an improved structure of semiconductor chips with enhanced die strength and a fabrication method thereof, in particular to an improved structure of semiconductor chips with enhanced die strength and a fabrication method thereof without beforehand back-etching of masking streets of the substrate, the substrate thereof is first thinned to have a thickness less than 100 μm, and then a backside metal layer is deposited to the backside of the substrate. By using the specific dicing process of the present invention, the chips can be diced tidily. The fabrication tool capacity can be increased; the process cycle time can be reduced to nearly half; the usage of material can be reduced; the efficiency of heat dissipation of the diced single chip can be increased; and the die strength can be significantly enhanced.

### BACKGROUND OF THE INVENTION

FIG. 1A are schematics showing the front and the back views of the substrate of integrated circuit chips. The right figure of FIG. 1A is a schematic showing the front views of integrated circuit chips, which comprises a substrate 101, and above the substrate 101 an active layer 103 is disposed, which includes at least one integrated circuit. As shown in the right figure of FIG. 1A, each black block corresponds to an independent integrated circuit. The left figure of FIG. 1A is a schematic showing the back views of integrated circuit chips. After the fabrication of integrated circuits, the substrate 101 has to be diced into independent single chips, so that each single chip contains an independent integrated circuit. A backside metal layer has to be deposited to the backside of the substrate 101 beforehand to provide improved adhesion strength and die strength for chip packaging thereafter. However, when a backside metal layer is directly deposited to the backside of the substrate 101, the fragments from the backside metal layer on the backside of the substrate 101 will be sprayed all around or adhered to the sidewall of scribe lines through the sawing wheel in the dicing process according to the conventional substrate dicing technique. Moreover, the metal fragments may adhere to the integrated circuits in the active layer 103, which will damage the function of integrated circuits in the active layer 103.

FIG. 1B is a schematic showing the cross-sectional view of the structure of an adhesive seed layer, a backside metal layer, and a photoresist layer formed on the backside of a substrate in a previous technology. After the fabrication of integrated circuits, the backside of the substrate 101 will be thinned first till the thickness of the substrate 101 is about 100 μm. Then, on the backside of the substrate 101, an adhesive seed layer 105, a backside metal layer 107, and a photoresist layer 109 are formed sequentially. FIG. 1C is a schematic showing the cross-sectional view of the structure of streets formed by etching the photoresist layer on the backside of the substrate in a previous technology. The streets 111 on the photoresist layer are formed by etching the photoresist layer 109. FIG. 1D is a schematic showing the cross-sectional view of the structure of streets formed by etching the backside metal layer on the backside of the substrate in a previous technology. The streets 113 on the backside metal layer are formed by etching the backside metal layer 107 and the adhesive seed layer 105. FIG. 1E is a schematic showing the cross-sectional view of the structure after removing the photoresist layer at the backside of the substrate in a previous technology.

FIG. 1F is a schematic showing the cross-sectional view of the structure of a substrate diced by the dicing process of a previous technology. The substrate 101 is diced along the center of the backside metal layer streets 113 to form scribe lines 115. The width of scribe lines 115 is narrower than the width of the backside metal layer streets 113 and thus it can prevent damages on the backside metal layer 107 and the adhesive seed layer 105. Independent single chips are produced after dicing, as shown by the schematic of a cross-sectional view of the structure of a single chip after substrate dicing in a previous technology in FIG. 1G. However, because the width of scribe lines 115 is narrower than the width of streets 113 on the backside metal layer, part of the backside metal layer streets 113 will not be cut off and will be remained there as the edge recess 117. There are borders between the substrate 101 and the adhesive seed layer 105 and between the adhesive seed layer 105 and the backside metal layer 107 at the edge recess 117. By etching the backside metal layer streets 113, the borders between the substrate 101 and the adhesive seed layer 105 and between the adhesive seed layer 105 and the backside metal layer 107 is not able to form tidy interface, and therefore cracks and chipping may occur at the die edge. Thereby, the die strength is often insufficient, which leads to high probability of the occurrence of die-crack.

In view of these facts and for overcoming the drawback stated above, the present invention provides a structure of semiconductor chips with enhanced die strength and a fabrication method thereof. The improved structure and the fabrication method according to the present invention not only have enhanced die strength, but also have improved heat conductance. The usage of material can be reduced, and the fabrication tool capacity can be increased, so that the fabrication cost can be significantly reduced.

### SUMMARY OF THE INVENTION

The main object of the present invention is to provide an improved structure of semiconductor chips with enhanced die strength and a fabrication method thereof, in which a backside metal layer is deposited directly to fully cover the backside of a substrate. The street masking step in the previous technology can be eliminated. Thereby the fabrication tool capacity can be increased, and the process cycle time can be reduced to nearly half. The fabrication cost can therefore be significantly reduced.

Another object of the present invention is to provide an improved structure of semiconductor chips with enhanced die strength and a fabrication method thereof, in which, before depositing a backside metal layer to the backside of a substrate, the backside of the substrate can be thinned first. The substrate can be thinned to have a thickness less than 50 μm. Consequently, when drilling, dry etching, or any further processing is applied to the substrate, the process cycle time can be significantly reduced. The processing tool capacity can be increased and the depletion of the processing tools can be decreased. The fabrication cost can therefore be significantly reduced.

Another object of the present invention is to provide an improved structure of semiconductor chips with enhanced die strength and a fabrication method thereof, in which a backside metal layer is deposited directly to fully cover the backside of a substrate. By applying the specific dicing process of the present invention, the backside metal layer and the substrate can be diced tidily. Die cracking on the border between the substrate and the backside metal layer of a single chip after dicing can be prevented and thereby the die strength can be significantly enhanced

Another object of the present invention is to provide an improved structure of semiconductor chips with enhanced die strength and a fabrication method thereof, in which a backside metal layer is deposited directly to fully cover the backside of a substrate. By applying the specific dicing process of the present invention, the die strength of a chip can be significantly enhanced. Because of the enhancement of the die strength, the thickness of the deposited backside metal layer can be thinner. A thickness of 3 μm of the backside metal layer is enough to provide the requested die strength. Thereby the amount of metal needed can be decreased, and the fabrication cost can therefore be significantly reduced.

Another object of the present invention is to provide an improved structure of semiconductor chips with enhanced die strength and a fabrication method thereof, in which, before depositing a backside metal layer to the backside of a substrate, the backside of the substrate can be thinned first. The substrate can be thinned to have a thickness less than 50 μm. Because the thickness of the substrate is thinned very thin, the efficiency of heat dissipation of a diced single chip in an application can be increased, which can prevent damages to the integrated circuits on the chip and maintain the performance of the integrated circuits on the chip.

Another object of the present invention is to provide an improved structure of semiconductor chips with enhanced die strength and a fabrication method thereof, in which, before depositing a backside metal layer to the backside of a substrate, the backside of the substrate can be thinned first. The substrate can be thinned to have a thickness less than 50 μm. The material thinned from the substrate can be recycled and then purified to make the substrate again, which can further reduce the fabrication cost.

Another object of the present invention is to provide an improved structure of semiconductor chips with enhanced die strength and a fabrication method thereof, in which by applying the specific dicing process of the present invention, the fragments from the backside metal layer will not be sprayed all around, and there will be no metal fragment adhesion to the integrated circuits on the chips, and therefore the performance of the integrated circuits in the active layer will not be affected, and the product yield rate can be increased.

Another object of the present invention is to provide an improved structure of semiconductor chips with enhanced die strength and a fabrication method thereof, in which by applying the specific dicing process of the present invention, the wasted width in the dicing process is about 30 μm, which is much less than the wasted width 60 μm of the masking streets in the previous technology. Therefore, the density of integrated circuits implemented in the active layer can be increased; the substrate utilization and the density of chips can be increased; the usage of material can be decreased, and the material cost can be reduced.

To reach the objects stated above, the present invention provides an improved structure of semiconductor chips with enhanced die strength, which comprises a substrate, an active layer, and a backside metal layer, in which the active layer is formed on the front side of the substrate and includes at least one integrated circuit; the backside metal layer is formed on the backside of the substrate, which fully covers the area corresponding to the area covered by the integrated circuits in the active layer.

In an embodiment, the area of the backside metal layer stated previously is larger than or equal to the area covered by the integrated circuits in the active layer.

In an embodiment, the backside metal layer stated previously can fully cover the backside of the substrate.

In an embodiment, the thickness of the substrate stated previously is larger than 10 μm and smaller than 200 μm; the thickness of the backside metal layer stated previously is larger than 0.1 μm and smaller than 50 μm; the material used for the substrate stated previously is preferably GaAs, SiC, GaN, Si or InP; the material used for the backside metal layer stated previously is preferably metal or alloy, and the metal is preferably gold or copper; and the backside metal layer stated previously is deposited to the backside of the substrate preferably by evaporation, electroplating, sputtering, or molecular beam epitaxy (MBE).

The present invention further provides a fabrication method of an improved structure of semiconductor chips with enhanced die strength, which includes the following steps:

forming an active layer on the front side of the substrate, which comprises at least one integrated circuit;

forming a backside metal layer on the backside of the substrate, which fully covers the area corresponding to the area covered by the integrated circuits in the active layer;

dicing the semiconductor chips with enhanced die strength by using a specific dicing process, whereby at least one single semiconductor chip with enhanced die strength is diced, and the backside metal layer fully covers the backside of the single semiconductor chip with enhanced die strength after dicing.

In an embodiment, the area of the backside metal layer of the single semiconductor chip with enhanced die strength stated previously is larger than or equal to the area of the substrate of the single semiconductor chip with enhanced die strength.

In an embodiment, the area of the backside metal layer stated previously is larger than or equal to the area covered by the integrated circuits in the active layer.

In an embodiment, the backside metal layer stated previously can fully cover the backside of the substrate.

The present invention provides a fabrication method for an improved structure of semiconductor chips with enhanced die strength, in which the backside of the substrate can be thinned before forming the backside metal layer thereon in the structure stated above.

In an embodiment, the thickness of the substrate stated previously is between 10 μm and 200 μm; the thickness of the backside metal layer is between 0.1 μm and 50 μm; the material used for the substrate stated previously is preferably GaAs, SiC, GaN, Si or InP; the material used for the backside metal layer is preferably metal or alloy, and the metal is preferably gold or copper; and the backside metal layer stated previously is deposited to the backside of the substrate preferably by evaporation, electroplating, sputtering or MBE.

To reach the objects stated above, the present invention further provides an improved structure of semiconductor chips with enhanced die strength, which comprises a substrate, an active layer, and a backside metal layer. The active layer is formed on the front side of the substrate and includes at least one integrated circuit. The backside metal layer is formed on the backside of the substrate, which fully covers the backside of the substrate.

In an embodiment, the area of the backside metal layer stated previously is larger than or equal to the area of the substrate.

In an embodiment, the thickness of the substrate stated previously is between 10 μm and 200 μm; the thickness of the backside metal layer stated previously is between 0.1 μm and 50 μm; the material used for the substrate is preferably GaAs, SiC, GaN, Si or InP; the material used for the backside metal layer is preferably metal or alloy, and the metal is preferably gold or copper; and the backside metal layer stated previously is deposited to the backside of the substrate preferably by evaporation, MBE, electroplating, or sputtering.

For further understanding the characteristics and effects of the present invention, some preferred embodiments referred to drawings are in detail described as follows.

### DETAILED DESCRIPTIONS OF PREFERRED EMBODIMENTS

FIG. 2A is a cross-sectional view of the structure of the substrate of integrated circuit chips of the present invention before back thinning, which comprises a substrate 201; an active layer 203 disposed above the substrate 201. The substrate 201 is formed preferably of GaAs, SiC, GaN, Si or InP. The active layer 203 includes at least one integrated circuit. In an embodiment, the active layer 203 usually includes multiple independent integrated circuits, which will be cut into multiple independent integrated circuit chips and then packaged to make product. A backside metal layer has to be deposited to the backside of the substrate 201 before dicing, which can enhance the die strength on one hand, and facilitate the adhesion in packaging on the other hand. In an embodiment, before depositing a backside metal layer to the backside of the substrate 201, the backside of the substrate 201 will be thinned first. The thickness of the substrate 201 is preferably larger than 10 μm and smaller than 200 μm after thinning. In an embodiment, the substrate 201 is thinned to have the thickness of about 50 m μm. FIG. 2B shows the cross-sectional view of the substrate of integrated circuit chips of the present invention after back thinning. It is shown in FIG. 2B that the substrate 201 becomes thinner after back thinning. The thinned backside of the substrate 201 is a region 207 for the backside metal layer deposition. Next, as shown in FIG. 2C, a schematic showing the cross-sectional view of the substrate with the deposited backside metal layer of the present invention, a backside metal layer 209 is deposited to the region 207 for the backside metal layer deposition. An adhesive seed layer (not shown in the figures) may grown on the region 207 for the adhesion of the backside metal layer 209 before depositing the backside metal layer 209 to the region 207. FIG. 2D is a schematic showing the partial enlarged view of the backside of the substrate of the present invention after back thinning and the backside metal layer deposition. The left figure of FIG. 2D is the backside of the substrate 201 after thinning, that is, the region 207 for the backside metal layer deposition, and the right figure of FIG. 2D shows a backside metal layer 209 deposited to the region 207 for the backside metal layer deposition. The backside metal layer is formed preferably of metal or alloy, and the metal is preferably gold or copper. The backside metal layer 209 is deposited to the region 207 on the backside of the substrate 201 preferably by evaporation, electroplating, sputtering or MBE. The thickness of the backside metal layer is larger than 0.1 μm and smaller than 50 μm. In an embodiment, the thickness of the backside metal layer is preferably around 3 μm. The backside metal layer 209 should be able to cover at least the backside area of the substrate 201 corresponding to the area covered by the integrated circuits in the active layer 203. Moreover, the backside metal layer 209 can be larger than or equal to the area covered by the integrated circuits in the active layer 203. In an embodiment, the region 207 on the backside of the substrate 201 can be completely covered by the deposited backside metal layer 209, which makes the fabrication process more simplified. After the deposition the backside metal layer 209, the dicing process can be proceeded. FIGS. 2E and 2F are schematics showing the partial enlarged view and the cross sectional view of the diced substrate of the present invention. A specific dicing process according to the present invention is used to form street scribe lines 211. The width of each scribe lines 211 is 30 μm. After dicing, each of the scribe lines 211 will waste about the width of 30 μm of the substrate 201 and the backside metal layer 209. By using the specific dicing process of the present invention, the fragments from the backside metal layer 209 will not be sprayed all around, and there will be no metal fragment adhered to the integrated circuits in the active layer 203, and therefore the performance of the integrated circuits in the active layer will not be affected, and the product yield rate can be improved.

After dicing, at least one single chip with enhanced die strength is diced. FIG. 2G is a schematic showing the cross-sectional view of the structure of a single chip of the present invention after substrate dicing. The diced single chip comprises: a substrate 201; an active layer 203 formed above the substrate 201, which includes at least on integrated circuit; a backside metal layer 209 is deposited to the backside of the substrate 201, which fully covers the backside of the substrate 201, and the area of the backside metal layer 209 is larger than or equal to the area of the substrate 201. The substrate 201 is formed preferably of GaAs, SiC, GaN, Si or InP. The thickness of the substrate 201 is preferably between 10 μm and 200 μm. In an embodiment, the preferable thickness of the substrate 201 is about 50 μm. The thickness of the backside metal layer 209 is preferably between 0.1 μm and 50 μm. In an embodiment, the preferable thickness of the backside metal layer 209 is about 3 μm. The material used for the backside metal layer 209 is preferably metal or alloy, and the metal is preferably gold or copper. The backside metal layer 209 is deposited to the backside of the substrate 201 preferably by evaporation, electroplating, sputtering or MBE. After dicing, the border between the substrate 201 and the backside metal layer 209 near the edge of the single chip is the border 215. By applying the specific dicing process of the present invention, the backside metal layer 209 and the substrate 201 can be cut tidily, and the composition at the border 215 remains intact, and therefore die cracking on the border 215 between the substrate 201 and the backside metal layer 209 can be prevented. Thereby, the die strength of the chips can be largely enhanced.

To sum up, by applying the specific dicing process of the present invention, the chip can be diced tidily without back etching of masking street beforehand, and the substrate can be thinned to have the thickness thinner than 100 μm. It can increase the fabrication tool capacity. The process cycle time can be reduced to nearly half, and the usage of materials can be reduced. The heat dissipation efficiency of the diced single chip can be improved, and the die strength will be largely enhanced. The present invention indeed can get its anticipatory object, and provide improved fabrication process stability and device reliability.

The description referred to the drawings stated above is only for the preferred embodiments of the present invention. Many equivalent local variations and modifications can still be made by those skilled at the field related with the present invention and do not depart from the spirits of the present invention, so they should be regarded to fall into the scope defined by the appended claims.

### BRIEF DESCRIPTION OF DRAWINGS

FIG. 1A is a schematic showing the front and the back views of the substrate of integrated circuit chips.

FIG. 1B is a schematic showing the cross-sectional view of the structure of an adhesive seed layer, a backside metal layer, and a photoresist layer formed on the backside of a substrate according to a previous technology.

FIG. 1C is a schematic showing the cross-sectional view of the structure of streets formed by etching the photoresist layer on the backside of a substrate according to a previous technology.

FIG. 1D is a schematic showing the cross-sectional view of the structure of streets formed by etching the backside metal layer on the backside of the substrate according to a previous technology.

FIG. 1E is a schematic showing the cross-sectional view of the structure after removing the photoresist layer at the backside of the substrate according to a previous technology.

FIG. 1F is a schematic showing the cross-sectional view of the structure of a diced substrate according to a previous technology.

FIG. 1G is a schematic showing the cross-sectional view of the structure of a single chip after substrate dicing according to a previous technology.

FIG. 2A is a schematic showing the cross-sectional view of the structure of the substrate of integrated circuit chips of the present invention before back thinning.

FIG. 2B is a schematic showing the cross-sectional view of the structure of the substrate of integrated circuit chips of the present invention after back thinning.

FIG. 2C is a schematic showing the cross-sectional view of the structure of a substrate with the deposited backside metal layer of the present invention.

FIG. 2D is a schematic showing the partial enlarged view of the backside of the substrate of the present invention after back thinning and the backside metal layer deposition.

FIG. 2E is a schematic showing the partial enlarged view of a diced substrate of the present invention.

FIG. 2F is a schematic showing the cross-sectional view of the structure of diced substrate of the present invention.

FIG. 2G is a schematic showing the cross-sectional view of the structure of a single chip of the present invention after substrate dicing.

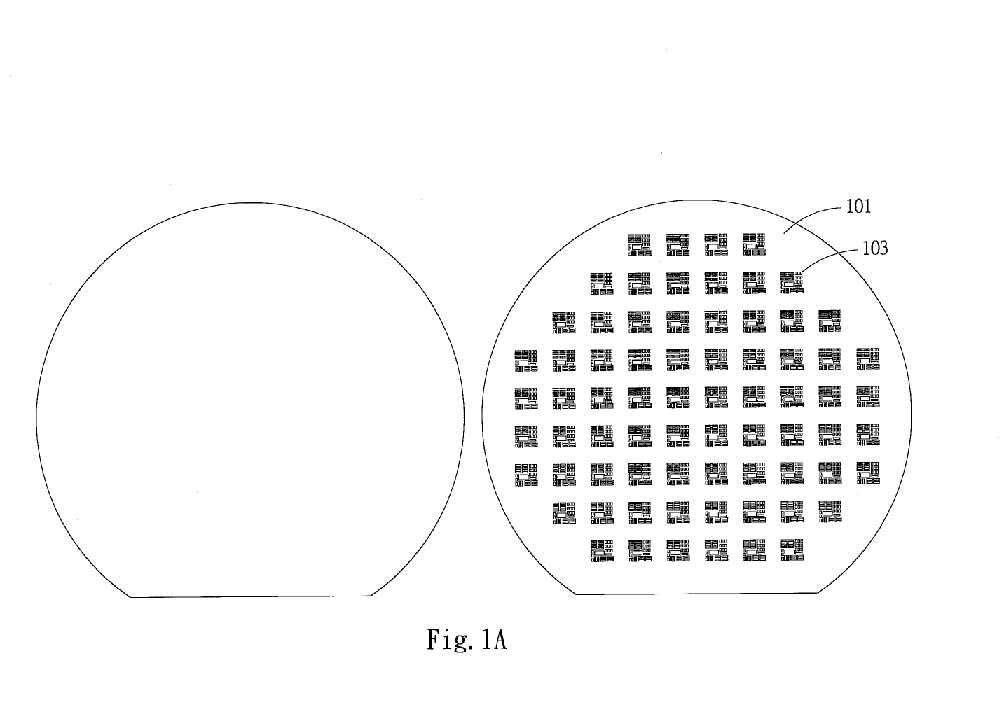

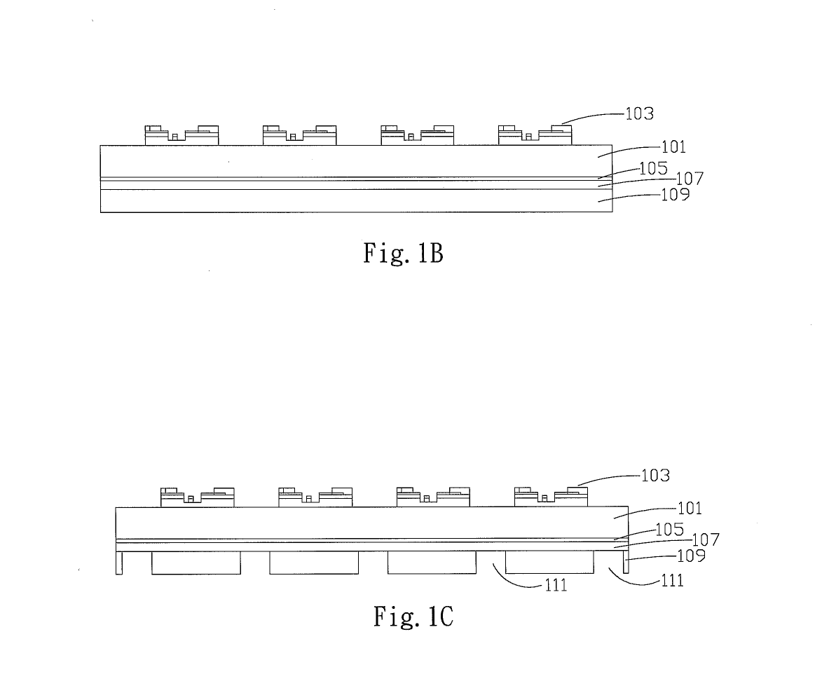

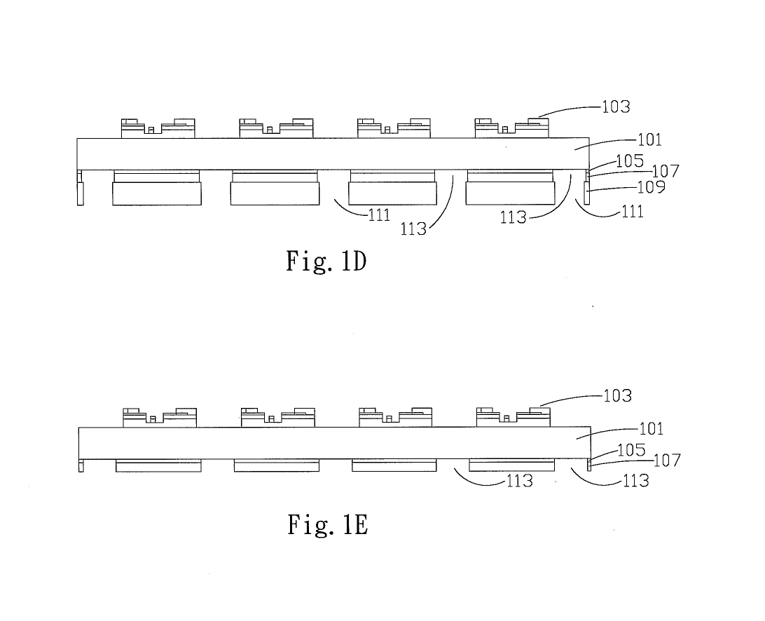

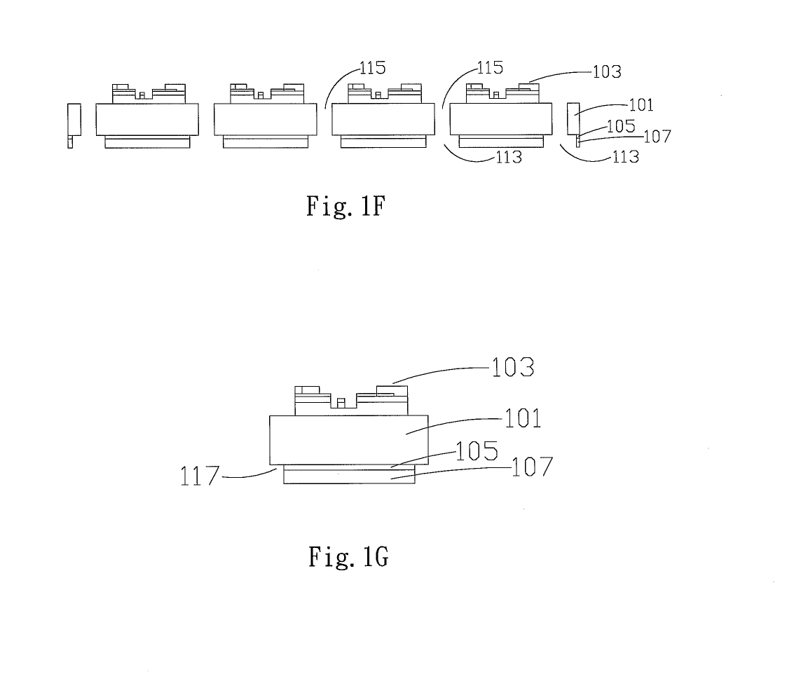

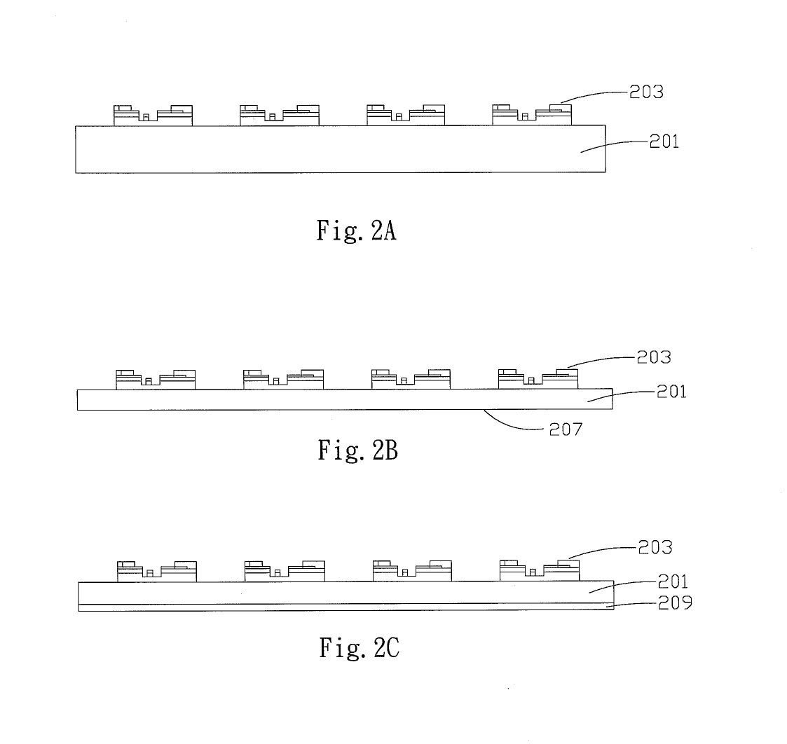

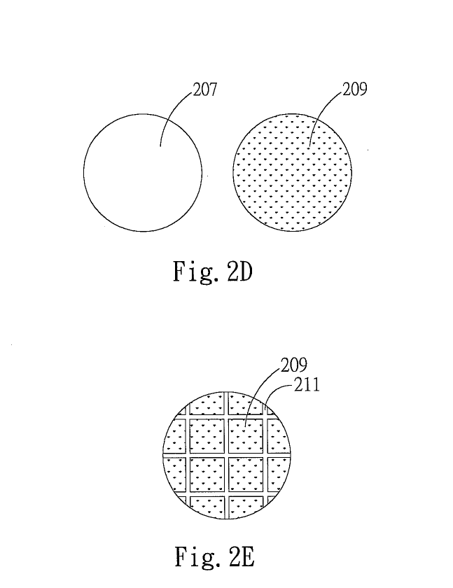

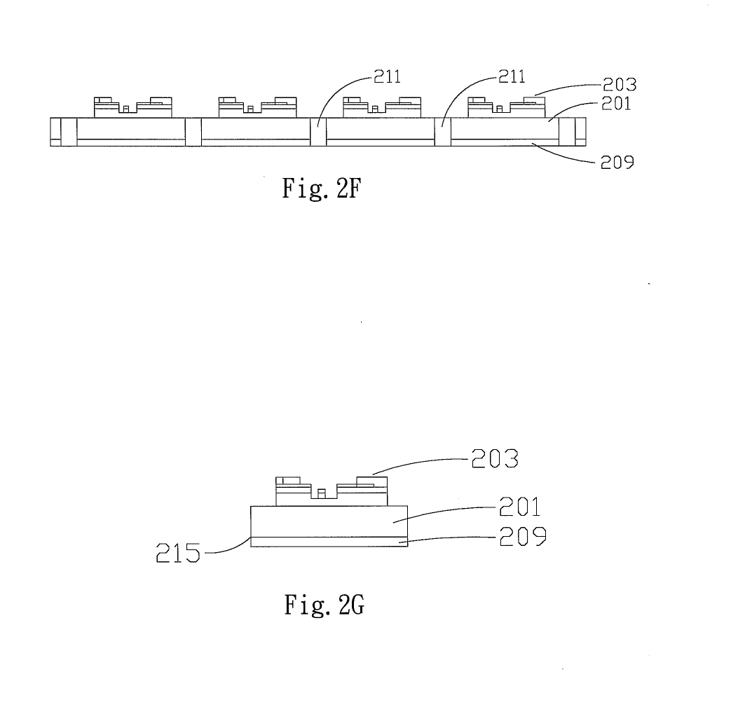

1. A structure of semiconductor chips with enhanced die strength comprising:
a substrate;
an active layer formed on the front side of said substrate, which comprises at least one integrated circuit; and
a backside metal layer formed on the backside of said substrate, which fully covers the area corresponding to the area covered by the integrated circuits in said active layer.

2. A structure of semiconductor chips with enhanced die strength according to claim 1, wherein the area of said backside metal layer is larger than or equal to the area covered by the integrated circuits in said active layer

3. A structure of semiconductor chips with enhanced die strength according to claim 1, wherein the thickness of said substrate is larger than 10 μm and smaller than 200 μm.

4. A structure of semiconductor chips with enhanced die strength according to claim 1, wherein said backside metal layer fully covers the backside of said substrate.

5. A structure of semiconductor chips with enhanced die strength according to claim 1, wherein the thickness of said backside metal layer is larger than 0.1 μm and smaller than 50 μm.

6. A structure of semiconductor chips with enhanced die strength according to claim 1, wherein the material used for said substrate is GaAs, SiC, GaN, Si or InP.

7. A structure of semiconductor chips with enhanced die strength according to claim 1, wherein the material used for said backside metal layer is metal or alloy.

8. A structure of semiconductor chips with enhanced die strength according to claim 7, wherein said metal is gold or copper.

9. A structure of semiconductor chips with enhanced die strength according to claim 1, wherein said backside metal layer is deposited to the backside of said substrate by evaporation, electroplating, sputtering or molecular beam epitaxy (MBE).

10. A structure of semiconductor chips with enhanced die strength comprising:
a substrate;
an active layer formed on the front side of said substrate, which comprises at least one integrated circuit; and
a backside metal layer formed on the backside of said substrate, which fully covers the backside of said substrate.

11. A structure of semiconductor chips with enhanced die strength according to claim 10, wherein the area of said backside metal layer is larger than or equal to the area of said substrate.

12. A structure of semiconductor chips with enhanced die strength according to claim 10, wherein the thickness of said substrate is larger than 10 μm in and smaller than 200 μm.

13. A structure of semiconductor chips with enhanced die strength according to claim 10, wherein the thickness of said backside metal layer is larger than 0.1 μm and smaller than 50 μm.

14. A structure of semiconductor chips with enhanced die strength according to claim 10, wherein the material used for said substrate is GaAs, SiC, GaN, Si or InP.

15. A structure of semiconductor chips with enhanced die strength according to claim 10, wherein the material used for said backside metal layer is metal or alloy.

16. A structure of semiconductor chips with enhanced die strength according to claim 15, wherein said metal is gold or copper.

17. A structure of semiconductor chips with enhanced die strength according to claim 10, wherein said backside metal layer is deposited to the backside of said substrate by evaporation, electroplating, sputtering or molecular beam epitaxy (MBE).

18. A fabrication method for a structure of semiconductor chips with enhanced die strength comprising the following steps:
forming an active layer on the front side of a substrate, which comprises at least one integrated circuit;
forming a backside metal layer on the backside of said substrate, which fully covers the area corresponding to the area covered by the integrated circuits in said active layer; and
dicing said semiconductor chips with enhanced die strength in a specific way, whereby at least one single chip is diced, and the backside metal layer of said single chip fully covers the backside of said single chip after dicing.

19. A fabrication method according to claim 18, wherein the area of the backside metal layer of said single chip is larger than or equal to the backside area of the substrate of said single chip.

20. A fabrication method according to claim 18, wherein the area of said backside metal layer is larger than or equal to the area covered by the integrated circuits in said active layer.

21. A fabrication method according to claim 18, wherein the backside of said substrate is thinned before forming said backside metal layer.

22. A fabrication method according to claim 21, wherein the thickness of said substrate is larger than 10 μm and smaller than 200 μm.

23. A fabrication method according to claim 18, wherein said backside metal layer fully covers the backside of said substrate.

24. A fabrication method according to claim 18, wherein the thickness of said backside metal layer is larger than 0.1 μm and smaller than 50 μm.

25. A fabrication method according to claim 18, wherein the material used for said substrate is GaAs, SiC, GaN, Si or InP.

26. A fabrication method according to claim 18, wherein the material used for said backside metal layer is metal or alloy.

27. A fabrication method according to claim 26, wherein said metal is gold or copper.

28. A fabrication method according to claim 18, wherein said backside metal layer is deposited to the backside of said substrate by evaporation, electroplating, sputtering or molecular beam epitaxy (MBE).
